(19) United States
(12) Patent Application Publication
(10) Pub. No.: US 2021/0292892 A1
(43) Pub. Date: Sep. 23, 2021

(54) SUBSTRATE PROCESSING APPARATUS

(71) Applicant: Kokusai Electric Corporation, Tokyo (JP)

(72) Inventor: Atsushi HIRANO, Toyama-shi (JP)

(73) Assignee: Kokusai Electric Corporation, Tokyo (JP)

(21) Appl. No.: 17/201,248

(22) Filed: Mar. 15, 2021

(30) Foreign Application Priority Data
Mar. 17, 2020 (JP) 2020-047038

(51) Int. Cl. C23C 16/44; C23C 16/455; H01L 21/67; C23C 16/52

(52) U.S. Cl. CPC C23C 16/4402; C23C 16/52; H01L 21/67017; C23C 16/45578

(57) ABSTRACT

Described herein is a technique capable of suppressing an undesired gas and a foreign substance from entering a supply buffer. According to one aspect thereof, there is provided a substrate processing apparatus including: a process vessel accommodating substrates and vertically arranged along an arrangement direction wherein the substrates are processed in the process vessel; a nozzle provided in the process vessel, provided with first openings arranged along the arrangement direction and configured to distribute and supply a gas to the substrates; and a supply buffer provided in the process vessel, accommodating the nozzle, and provided with second openings arranged along the arrangement direction and open toward a substrate arrangement region in the process vessel where the substrates are arranged, wherein at least one among the first openings is arranged to be prevented from directly facing the second openings.

### CROSS-REFERENCE TO RELATED PATENT APPLICATION

This non-provisional U.S. patent application claims priority under 35 U.S.C. § 119 of Japanese Patent Application No. 2020-047038, filed on Mar. 17, 2020, in the Japanese Patent Office, the entire contents of which are hereby incorporated by reference.

### BACKGROUND

### 1. Field

The present disclosure relates to a substrate processing apparatus.

### 2. Related Art

A semiconductor manufacturing apparatus may be used as an example of a substrate processing apparatus, and a vertical type semiconductor manufacturing apparatus (hereinafter, also referred to as a “vertical type apparatus”) may be used as an example of the semiconductor manufacturing apparatus. For example, the vertical type apparatus includes a boat serving as a substrate retainer capable of supporting a plurality of substrates in a multistage manner. The boat is transferred into a reaction tube of the vertical type apparatus while the plurality of the substrates are supported by the boat, and the plurality of the substrates supported by the boat are processed in a process chamber in the reaction tube.

According to some related arts, there is disclosed a substrate processing apparatus provided with a gas supply area. The gas supply area is provided outside a side wall of a cylinder constituting the reaction tube, and a process gas supplier (which is a process gas supply system) is connected to the gas supply area. A boundary wall between the gas supply area and an inner portion of the cylinder is a part of the side wall of the cylinder, and a plurality of gas supply slits elongated in a circumferential direction of the cylinder and configured to supply a process gas into the cylinder are provided corresponding to the plurality of the substrates. That is, the plurality of the gas supply slits are aligned in a vertical direction. A lower end of the gas supply area is open, and a nozzle can be inserted into the gas supply area through the open lower end (that is, a lower end opening) of the gas supply area.

According to the substrate processing apparatus provided with the gas supply area described above, the gas supply area may communicate with the inner portion of the cylinder by the plurality of the gas supply slits or the lower end opening. As a result, depending on pressure conditions, a gas such as the process gas in the cylinder may enter the gas supply area through the plurality of the gas supply slits or the lower end opening. Thereby, by-products may be deposited in the gas supply area, and particles may be supplied to the plurality of the substrates together with the gas.

### SUMMARY

Described herein is a technique capable of suppressing an undesired gas and a foreign substance from entering a supply buffer.

According to one aspect of the technique of the present disclosure, there is provided a substrate processing apparatus including: a process vessel accommodating a plurality of substrates comprising a substrate and vertically arranged along an arrangement direction wherein the plurality of the substrates are processed in the process vessel; a nozzle provided in the process vessel, provided with a plurality of first openings arranged along the arrangement direction and configured to distribute and supply a gas to the plurality of the substrates; and a supply buffer provided in the process vessel, accommodating the nozzle, and provided with a plurality of second openings arranged along the arrangement direction and open toward a substrate arrangement region in the process vessel where the plurality of the substrates are arranged, wherein at least one among the first openings is arranged to be prevented from directly facing the plurality of the second openings.

### BRIEF DESCRIPTION OF THE DRAWINGS

FIG. 1 schematically illustrates a configuration of a substrate processing apparatus according to one or more embodiments described herein.

FIG. 2 schematically illustrates a horizontal cross-section of a vertical type process furnace of the substrate processing apparatus according to the embodiments described herein.

FIG. 3 is a perspective view schematically illustrating a cross-section of the vertical type process furnace of the substrate processing apparatus according to the embodiments described herein.

FIG. 4 schematically illustrates a vertical cross-section of the vertical type process furnace of the substrate processing apparatus according to the embodiments described herein.

FIG. 5 is an enlarged view schematically illustrating an upper portion of the vertical type process furnace of the substrate processing apparatus according to the embodiments described herein.

FIG. 6 is a block diagram schematically illustrating a configuration of a controller of the substrate processing apparatus and related components of the substrate processing apparatus according to the embodiments described herein.

FIG. 7 is an enlarged view schematically illustrating a horizontal cross-section of a part of the vertical type process furnace for explaining an opening direction of a nozzle according to a first modified example.

FIG. 8 is an enlarged view schematically illustrating a horizontal cross-section of a part of the vertical type process furnace for explaining an opening direction of a nozzle according to a second modified example.

FIG. 9 is an enlarged view schematically illustrating a horizontal cross-section of a part of the vertical type process furnace for explaining an opening direction of a nozzle according to a third modified example.

FIG. 10 is an enlarged view schematically illustrating a horizontal cross-section of a part of the vertical type process furnace for explaining an opening direction of a nozzle according to a fourth modified example.

FIG. 11 schematically illustrates a central flow velocity of each wafer.

FIG. 12 schematically illustrates wafer-to-wafer (WtW) characteristics of each wafer.

FIG. 13 schematically illustrates within-wafer (WiW) characteristics of each wafer.

### DETAILED DESCRIPTION

### Embodiments

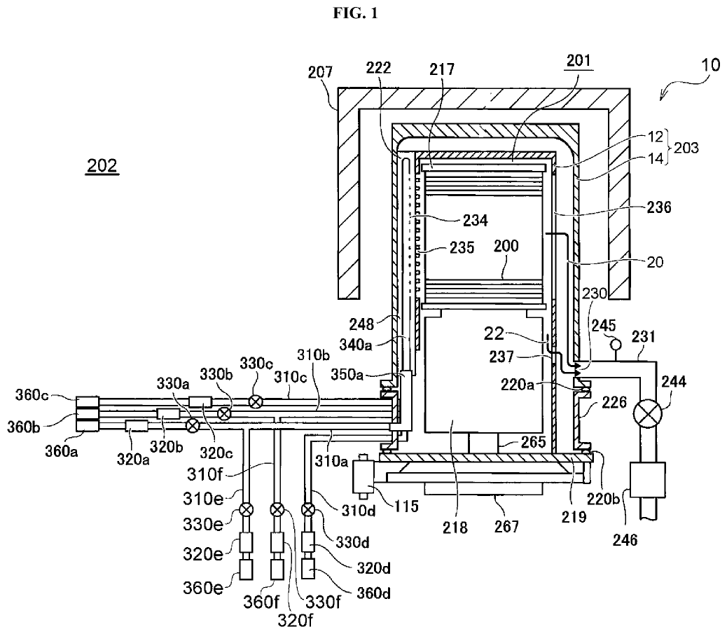

Hereinafter, one or more embodiments (also simply referred to as “embodiments”) according to the technique of the present disclosure will be described with reference to the drawings. FIG. 1 schematically illustrates a configuration of a substrate processing apparatus 10 according to the embodiments described herein. The substrate processing apparatus 10 is used for manufacturing a semiconductor device.

The substrate processing apparatus 10 includes a vertical type process furnace (also simply referred to as a “process furnace”) 202. The process furnace 202 includes a heater 207 serving as a heating apparatus (heating structure). The heater 207 is of a cylindrical shape, and is vertically installed while being supported by a heater base (not shown). The heater 207 also functions as an activator (exciter) capable of activating (exciting) a process gas by heat.

A reaction tube 203 is provided in an inner side of the heater 207. A reaction vessel is constituted by the reaction tube 203. For example, the reaction tube 203 is made of a heat resistant material such as quartz (SiO₂) and silicon carbide (SiC). The reaction tube 203 is an example of a process vessel capable of accommodating (supporting) a plurality of wafers including a wafer 200 serving as a substrate vertically arranged in a horizontal orientation in a multistage manner. Hereinafter, the plurality of the wafers may also be simply referred to as wafers 200. The wafers 200 are processed in the reaction tube 203.

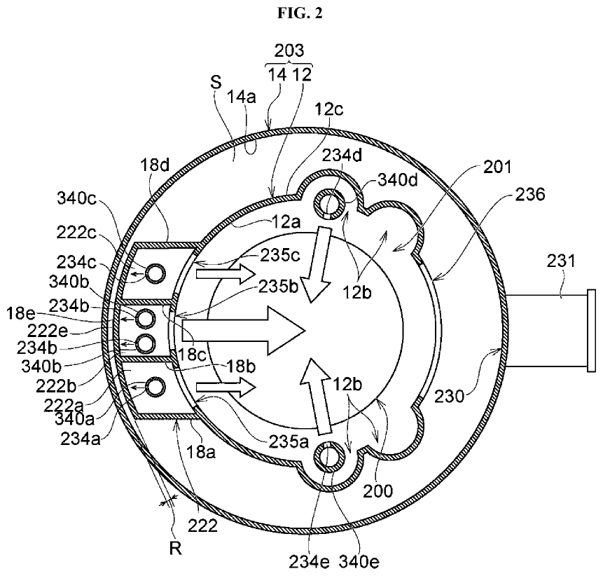

The reaction tube 203 is constituted by at least an inner tube 12 of a cylindrical shape. According to the present embodiments, as shown in FIG. 2, the reaction tube 203 includes the inner tube 12 of a cylindrical shape and an outer tube 14 of a cylindrical shape provided so as to surround the inner tube 12. The inner tube 12 is provided concentrically with the outer tube 14, and a gap S is provided between the inner tube 12 and the outer tube 14.

As shown in FIG. 1, the inner tube 12 includes a ceiling and is provided with an open lower end and a closed upper end. The upper end of the inner tube 12 is closed by a flat wall body. The outer tube 14 also includes a ceiling and is provided with an open lower end and a closed upper end. The upper end of the outer tube 14 is closed by a flat wall body.

As shown in FIG. 2, a nozzle arrangement chamber 222 is provided in the gap S defined between the inner tube 12 and the outer tube 14. The nozzle arrangement chamber 222 serving as a supply buffer is provided in the reaction tube 203 and is configured to accommodate a plurality of gas nozzles 340a, 340b and 340c described later. A plurality of gas supply slits 235 (for example, gas supply slits 235a, gas supply slits 235b and gas supply slits 235c) serving as a plurality of second openings are provided on a circumferential wall of the inner tube 12 between the nozzle arrangement chamber 222 and a wafer arrangement region of the reaction tube 203 along a vertical direction. That is, the gas supply slits 235a, 235b and 235c are open toward the wafer arrangement region. The gas supply slits 235a, 235b and 235c serving as the second openings are configured to restrict fluid communication therearound. The gas supply slits 235a, 235b and 235c are provided on the circumferential wall of the inner tube 12 at locations corresponding to each of the wafers 200 over a region (that is, the wafer arrangement region) of a process chamber 201 in which the wafers 200 are accommodated from a lower end to an upper end of the wafer arrangement region. The nozzle arrangement chamber 222 serving as the supply buffer may be provided at the outer tube 14.

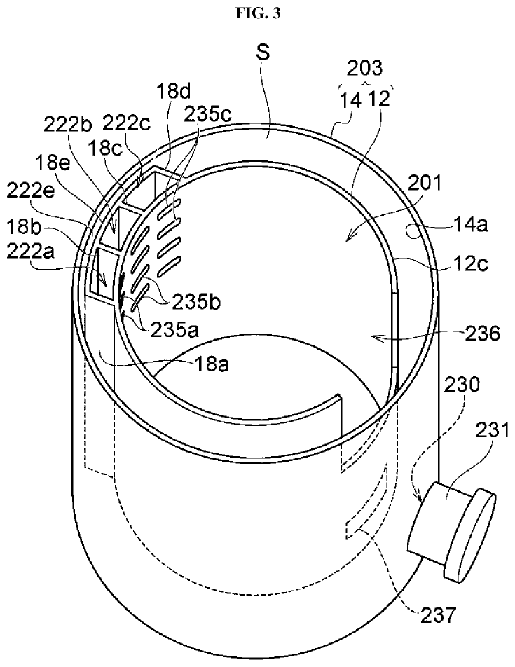

As shown in FIG. 3, a first gas exhaust port 236, which is an example of an outflow port, is provided at a portion of the circumferential wall of the inner tube 12 facing the gas supply slits 235a, 235b and 235c. A second gas exhaust port 237, which is an example of an outflow port whose opening area is smaller than that of the first gas exhaust port 236, is provided below the first gas exhaust port 236.

As shown in FIG. 1, an inner side of the inner tube 12 constitutes the process chamber 201. The wafer 200 serving as a substrate is processed in the process chamber 201.

The process chamber 201 is configured to accommodate a boat 217, which is an example of a substrate retainer capable of accommodating the wafers 200 vertically arranged in a horizontal orientation in a multistage manner. The inner tube 12 is configured to surround the wafers 200 accommodated in the boat 217.

The lower end of the reaction tube 203 is supported by a manifold 226 of a cylindrical shape. For example, the manifold 226 is made of a metal such as nickel alloy and stainless steel, or is made of a heat resistant material such as quartz (SiO₂) and silicon carbide (SiC). A flange (not shown) is provided at an upper end of the manifold 226, and the lower end of the reaction tube 203 is provided on the flange and supported by the flange.

A seal 220a such as an O-ring is provided between the flange and the upper end of the reaction tube 203 to airtightly seal an inside of the reaction tube 203.

A seal cap 219 is airtightly attached to a lower end opening of the manifold 226 via a seal 220b such as an O-ring. The seal cap 219 is configured to airtightly seal a lower end opening of the reaction tube 203, that is, the lower end opening of the manifold 226. For example, the seal cap 219 is made of a metal such as nickel alloy and stainless steel, and is of a disk shape. The seal cap 219 may be configured such that an outer surface of the seal cap 219 is covered with a heat resistant material such as quartz (SiO₂) and silicon carbide (SiC).

A boat support 218 configured to support the boat 217 is provided on the seal cap 219. The boat support 218 is made of a heat resistant material such as quartz and SiC. The boat support 218 also functions as a heat insulator.

The boat 217 is provided vertically on the boat support 218. For example, the boat 217 is made of a heat resistant material such as quartz and SiC. The boat 217 includes a bottom plate (not shown) fixed to the boat support 218 and a top plate (not shown) provided above the bottom plate. A plurality of support columns (not shown) are provided between the bottom plate and the top plate. The support columns are installed to connect the bottom plate and the top plate. Each of the support columns is provided with a plurality of grooves or a plurality of pins to reliably support the wafers 200.

The boat 217 accommodates the wafers 200 processed in the process chamber 201 in the inner tube 12. The wafers 200 are horizontally oriented with predetermined intervals therebetween. That is, the wafers 200 are supported by the support columns of the boat 217 with their centers aligned with each other. A stacking direction of the wafers 200 are is equal to an axial direction of the reaction tube 203.

A boat rotator 267 configured to rotate the boat 217 is provided below the seal cap 219. A rotating shaft 265 of the boat rotator 267 is connected to the boat support 218 through the seal cap 219. As the boat rotator 267 rotates the boat 217 via the boat support 218, the wafers 200 supported by the boat 217 are rotated.

The seal cap 219 may be elevated or lowered in the vertical direction by a boat elevator 115 provided outside the reaction tube 203. The boat elevator 115 serves as an elevator. As the seal cap 219 is elevated or lowered in the vertical direction by the boat elevator 115, the boat 217 is transferred (loaded) into the process chamber 201 or transferred (unloaded) out of the process chamber 201.

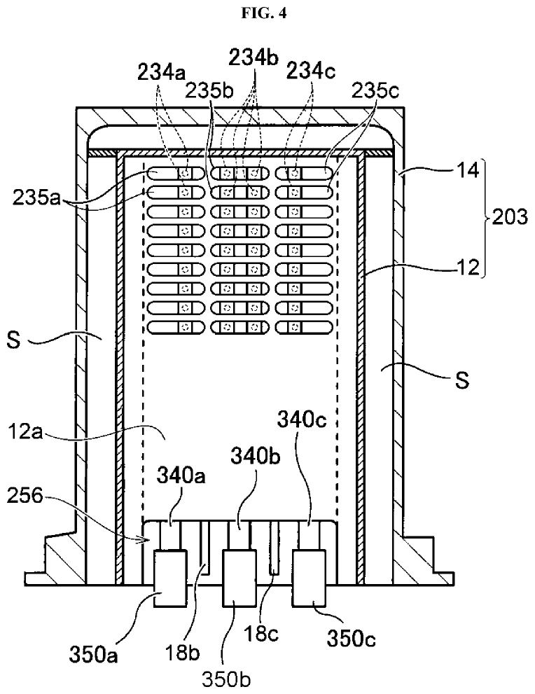

A plurality of nozzle supports 350a, 350b and 350c, which are shown in FIG. 4 and configured to support a plurality of gas nozzles 340a, 340b, 340c, 340d and 340e, respectively, are installed at the manifold 226 so as to pass through the manifold 226.

According to the present embodiments, for example, three nozzle supports 350a through 350c shown in FIG. 4 and two nozzle supports (not shown) are installed. For example, the nozzle supports 350a through 350c are made of a material such as nickel alloy and stainless steel.

A plurality of gas supply pipes 310a, 310b and 310c configured to supply gases such as the process gas into the process chamber 201 are connected to first ends of the nozzle supports 350a through 350c (which are shown in FIG. 4), respectively. The two nozzle supports (not shown) to which the gas nozzles 340d and 340e are connected to corresponding gas supply pipes (not shown), respectively.

The gas nozzles 340a through 340d are connected to second ends of the nozzle supports 350a through 350c shown in FIG. 4, respectively. For example, the gas nozzles 340a through 340e are made of a heat resistant material such as quartz and SiC.

A first source gas supply source 360a capable of supplying a first source gas, a mass flow controller (MFC) 320a serving as a flow rate controller and a valve 330a serving as an opening/closing valve are sequentially provided in order at the gas supply pipe 310a from an upstream side toward a downstream side of the gas supply pipe 310a. A second source gas supply source 360b capable of supplying a second source gas, a mass flow controller (MFC) 320b and a valve 330b are sequentially provided in order at the gas supply pipe 310b from an upstream side toward a downstream side of the gas supply pipe 310b. The first source gas and the second source gas may be collectively or individually referred to as a “source gas”.

An inert gas supply source 360c capable of supplying an inert gas, a mass flow controller (MFC) 320c and a valve 330c are sequentially provided in order at the gas supply pipe 310c from an upstream side toward a downstream side of the gas supply pipe 310c. An inert gas supply source 360d capable of supplying the inert gas, a mass flow controller (MFC) 320d and a valve 330d are sequentially provided in order at a gas supply pipe 310d from an upstream side toward a downstream side of the gas supply pipe 310d.

A gas supply pipe 310e configured to supply the inert gas is connected to the gas supply pipe 310a at a downstream side of the valve 330a. An inert gas supply source 360e capable of supplying the inert gas, a mass flow controller (MFC) 320e and a valve 330e are sequentially provided in order at the gas supply pipe 310e from an upstream side toward a downstream side of the gas supply pipe 310e. A gas supply pipe 310f configured to supply the inert gas is connected to the gas supply pipe 310b at a downstream side of the valve 330b. An inert gas supply source 360f capable of supplying the inert gas, a mass flow controller (MFC) 320f and a valve 330f are sequentially provided in order at the gas supply pipe 310f from an upstream side toward a downstream side of the gas supply pipe 310f. The inert gas supply sources 360c through 360e capable of supplying the inert gas may be connected to a common supply source capable of supplying the inert gas.

As the first source gas supplied through the gas supply pipe 310a, ammonia (NH₃) gas may be used. As the second source gas supplied through the gas supply pipe 310b, a silicon (Si) source gas may be used. As the inert gas supplied through each of the gas supply pipes 310c, 310d, 310e and 310f, nitrogen (N₂) gas may be used.

An exhaust port 230 is provided at the outer tube 14 of the reaction tube 203. The exhaust port 230 is provided below the second gas exhaust port 237. An exhaust pipe 231 is connected to the exhaust port 230.

A vacuum pump 246 serving as a vacuum exhauster is connected to the exhaust pipe 231 through a pressure sensor 245 and an APC (Automatic Pressure Controller) valve 244. The pressure sensor 245 serves as a pressure detector to detect an inner pressure of the process chamber 201, and the APC valve 244 serves as a pressure regulator. The exhaust pipe 231 at a downstream side of the vacuum pump 246 is connected to a component such as a waste gas processing apparatus (not shown). By controlling an output of the vacuum pump 246 and adjusting an opening degree of the APC valve 244, it is possible to vacuum-exhaust an inner atmosphere of the process chamber 201 such that the inner pressure of the process chamber 201 reaches and is maintained at a predetermined pressure (vacuum degree).

The APC valve 244 serves as an opening/closing valve. With the vacuum pump 246 in operation, the APC valve 244 may be opened or closed to vacuum-exhaust the inner atmosphere of the process chamber 201 or to stop the vacuum-exhaust. By adjusting the opening degree of the APC valve 244, the APC valve 244 is configured to adjust the inner pressure of the process chamber 201 by adjusting a conductance thereof.

A temperature sensor (not shown) serving as a temperature detector is provided in the reaction tube 203. The electrical power supplied to the heater 207 is adjusted based on temperature information detected by the temperature sensor such that a desired temperature distribution of an inner temperature of the process chamber 201 is obtained.

In the process furnace 202 described above, the boat 217 is transferred into the process chamber 201 while being supported by the boat support 218 in a state where the wafers to be batch-processed are stacked in the boat 217 in a multistage manner. Then, the wafers 200 loaded in the process chamber 201 is heated by the heater 207 to a predetermined temperature.

Hereinafter, the configuration of the reaction tube 203 will be described in detail with reference to FIGS. 2 through 5. In FIG. 3, the illustrations of components such as the gas nozzles 340a through 340e and the boat 217 are omitted for simplification.

As shown in FIGS. 2 and 3, the gas supply slits 235a through 235c configured to supply the gases such as the process gas is provided at the inner tube 12. The nozzle arrangement chamber 222 and the process chamber 201 communicate with each other through the gas supply slits 235a through 235c.

The nozzle arrangement chamber 222 is provided in the gap S of a ring shape between an outer circumferential surface 12c of the inner tube 12 and an inner circumferential surface 14a of the outer tube 14. The nozzle arrangement chamber 222 is constituted by a first nozzle arrangement chamber (also simply referred to as a “first chamber”) 222a, a second nozzle arrangement chamber (also simply referred to as a “second chamber”) 222b and a third nozzle arrangement chamber (also simply referred to as a “third chamber”) 222c. The chambers 222a, 222b and 222c are arranged side by side in a circumferential direction of the gap S of a ring shape.

The first chamber 222a is provided between a first partition 18a and a second partition 18b which extend from the outer circumferential surface 12c of the inner tube 12 toward the outer tube 14. A front wall of the first chamber 222a facing the reaction tube 203 is constituted by the circumferential wall of the inner tube 12, and a rear wall of the first chamber 222a facing the outer tube 14 is constituted by a connecting wall 18e connecting an edge of the first partition 18a and an edge of the second partition 18b. That is, the first chamber 222a is surrounded by the connecting wall 18e, the circumferential wall of the inner tube 12, the first partition 18a and the second partition 18b.

The second chamber 222b is provided between the second partition 18b and a third partition 18c which extend from the outer circumferential surface 12c of the inner tube 12 toward the outer tube 14. A front wall of the second chamber 222b facing the reaction tube 203 is constituted by the circumferential wall of the inner tube 12, and side walls of the second chamber 222b are constituted by the second partition 18b and the third partition 18c.

A rear wall of the second chamber 222b facing the outer tube 14 is constituted by the connecting wall 18e connecting the edge of the second partition 18b and an edge of the third partition 18c. That is, the second chamber 222b is surrounded by the connecting wall 18e, the circumferential wall of the inner tube 12, the second partition 18b and the third partition 18c.

The third chamber 222c is provided between the third partition 18c and a fourth partition 18d which extend from the outer circumferential surface 12c of the inner tube 12 toward the outer tube 14. A front wall of the third chamber 222c facing the reaction tube 203 is constituted by the circumferential wall of the inner tube 12, and a rear wall of the third chamber 222c facing the outer tube 14 is constituted by the connecting wall 18e connecting the edge of the third partition 18c and an edge of the fourth partition 18d. That is, the third chamber 222c is surrounded by the connecting wall 18e, the circumferential wall of the inner tube 12, the third partition 18c and the fourth partition 18d.

It is preferable that a separation distance R from the connecting wall 18e to a circumferential wall of the outer tube 14 may range from 1 mm to 5 mm, more preferably from 2 mm to 5 mm.

The partitions 18a through 18d and the connecting wall 18e are provided from the upper end to the lower end of the inner tube 12. Each of the chambers 222a through 222c includes a ceiling and is provided with an open lower end and a closed upper end. The open lower end of each of the chambers 222a through 222c serves as a nozzle insertion port 256, and the closed upper end of each of the chambers 222a through 222c is closed by a flat wall body.

As shown in FIG., the gas nozzles 340a through 340c which extend in the vertical direction are provided in the respective chambers 222a through 222c of the nozzle arrangement chamber 222. Each of the gas nozzles 340a through 340c is an example of a nozzle provided in the reaction tube 203 and configured to distribute and supply the gases to the wafers 200.

Adjacent gas nozzles among the gas nozzles 340a through 340c are partitioned by the partitions 18b and 18c. Therefore, it is possible to suppress the gases such as the process gas supplied through the gas nozzles 340a through 340c from mixing with one another in the nozzle arrangement chamber 222. Without the partitions 18b and 18c being installed, a vortex may be generated to flow along an inner wall of the nozzle arrangement chamber 222 when the gas is ejected through one of the gas nozzles 340a through 340c. Thereby, the gas tends to become stagnant in the nozzle arrangement chamber 222, and the gas may not be efficiently supplied from the nozzle arrangement chamber 222 to the wafer arrangement region. Further, without the front wall (that is, the circumferential wall of the inner tube 12) being installed, a vortex may be generated to flow back and forth (into and out of) through the inner tube 12 when the gas is ejected through one of the gas nozzles 340a through 340c. Thereby, the gas may not be efficiently supplied from the nozzle arrangement chamber 222 to the wafer arrangement region.

It would be sufficient as long as inner spaces of the first chamber 222a, the second chamber 222b and the third chamber 222c are separated from one another. As such, the first chamber 222a, the second chamber 222b and the third chamber 222c are not limited to the above-described configuration in which the second partition 18b and the third partition 18c are shared between the first chamber 222a and the second chamber 222b and between the second chamber 222b and the third chamber 222c, respectively. For example, even if a slight gap is provided between the first chamber 222a and the second chamber 222b or between the second chamber 222b and the third chamber 222c, it can be said that the chambers 222a through 222c are substantially arranged side by side in a consecutive manner when the gap is smaller than a minimum width of each of the first chamber 222a, the second chamber 222b and the third chamber 222c.

Arc-shaped dents 12b curved outward from an inner circumferential surface 12a are provided on the circumferential wall of the inner tube 12. Two pairs of the dents 12b may be provided at each of two locations beside (left and right of) the first gas exhaust port 236. As shown in FIG. 2, the gas nozzles 340d may be arranged at one among a pair of the dents 12b that is closer to the nozzle arrangement chamber 222, and the gas nozzles 340e is arranged at one among the other pair of the dents 12b that is closer to the nozzle arrangement chamber 222.

Each of the gas nozzles 340a, 340c, 340d and 340e is configured as an I-shaped long nozzle. The gas nozzle 340b is configured as a return nozzle constituted by an ascending pipe and a descending pipe. One of the two pipes indicated by the reference numeral 340b shown in FIG. 2 is the ascending pipe (first pipe) of the gas nozzle 340b, and the other is the descending pipe (second pipe) of the gas nozzle 340b. The ascending pipe of the gas nozzle 340b and the descending pipe of the gas nozzle 340b are capable of fluidically communicating with each other by upper ends thereof being connected, and the gas supply pipe 310b is connected to a lower end of the ascending pipe. A plurality of gas supply holes 234 (for example, gas supply holes 234a, gas supply holes 234b, gas supply holes 234c, gas supply holes 234d and gas supply holes 234e) serving as a plurality of first openings arranged along the vertical direction are provided on side surfaces of the gas nozzles 340a through 340e, respectively. In the gas nozzle 340b, the gas supply holes 234b are provided in each of the ascending pipe and the descending pipe at locations corresponding to the positions of the wafers 200. The gas nozzle 340b is not limited to the return nozzle described above. For example, the gas nozzle 340b may be configured as a nozzle array constituted by a plurality of pipes extending in the vertical direction and fluidically communicating with each other. The nozzle array may simultaneously eject the gases supplied from the plurality of the pipes through the entire gas supply holes 234b.

An opening area of each of the gas supply holes 234a, 234b and 234c or a total area of the gas supply holes 234a, 234b and 234c is smaller than an opening area of the each of the gas supply slits 235a through 235c or a total area of the gas supply slits 235a through 235c. As a result, a pressure loss in the gas supply holes 234a, 234b and 234c is larger than a pressure loss in the gas supply slits 235a through 235c. A gas supply structure (which is a gas supplier) in the nozzle arrangement chamber 222 functions as a buffer capable of moderating unbalance in gas supply by performing two steps of the restricted fluid communication. By allowing the relatively large pressure loss of the gas supply holes 234a, 234b and 234c, it is possible to further uniformize an ejection amount of the gas ejected from each of the gas nozzles 340a, 340b and 340c through each of the gas supply holes 234a, 234b and 234c, and it is also possible to uniformly fill the nozzle arrangement chamber 222 with the gas such as the process gas. Thus, by allowing the relatively large pressure loss of the gas supply holes 234a, 234b and 234c, the gas supply structure in the nozzle arrangement chamber 222 may effectively function as the buffer. On the other hand, an initial velocity at each of the gas supply holes 234 becomes faster. Thus, when the gas passes through the gas supply slits 235 while maintaining a high velocity, a velocity of the gas may decrease or a backflow of the gas may be generated at other locations of the gas supply slits 235. That is, a flow velocity distribution along a longitudinal direction of the gas supply slits 235 may be non-uniform. Further, the high initial velocity of the gas may cause an inner pressure of the nozzle arrangement chamber 222 to become lower than an inner pressure of the inner tube 12. Thereby, the gas may be sucked through the nozzle insertion port 256.

According to the present embodiments, at least one among the gas supply holes 234 may be arranged without directly facing the gas supply slits 235. Specifically, as shown in FIG. 2, the gas supply holes 234a, 234b and 234c are open toward the connecting wall 18e. That is, the gas supply holes 234a, 234b and 234c are open toward a radial direction of the reaction tube 203. The connecting wall 18e is disposed radially opposite to the circumferential wall of the inner tube 12 on which the gas supply slits 235a, 235b and 235c are provided.

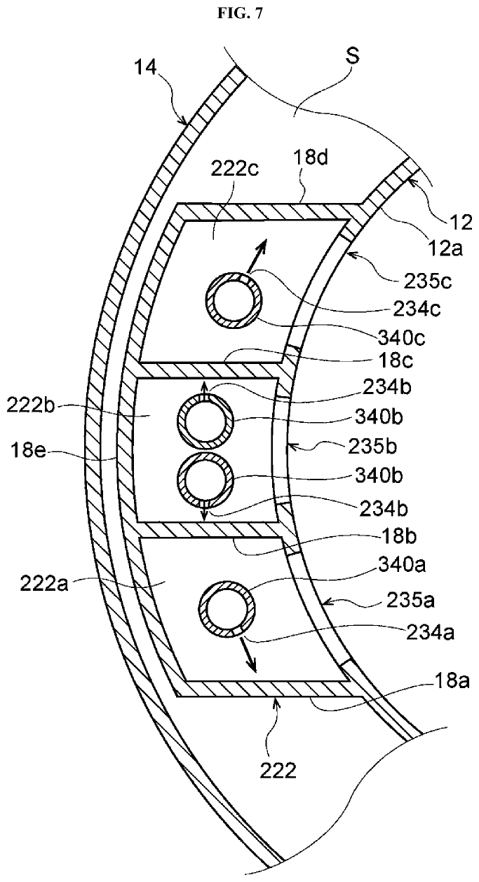

The arrangement of the gas supply holes 234 is not limited to the arrangement described above. For example, the gas supply holes 234 may be arranged according to a first modified example through a fourth modified example shown in FIGS. 7 through 10. According to the first modified example shown in FIG. 7, the gas supply holes 234a are disposed at such locations of the gas nozzle 340a as to face toward a circumferential direction of the reaction tube 203. For example, the gas supply holes 234a are open toward the first partition 18a in which none of the gas supply slits 235a are provided. The gas supply holes 234b are disposed at such locations of the gas nozzle 340b as to face toward the circumferential direction of the reaction tube 203. For example, the gas supply holes 234b are open toward the second partition 18b and the third partition 18c in which none of the gas supply slits 235b are provided. The gas supply holes 234c are disposed at such locations of the gas nozzle 340c as to face toward the circumferential direction of the reaction tube 203. For example, the gas supply holes 234c are open toward the fourth 18d in which none of the gas supply slits 235c are provided.

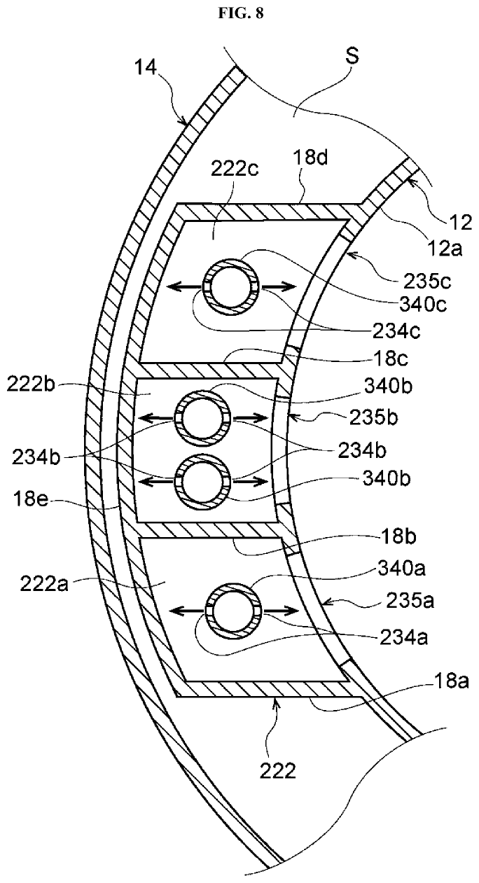

According to the second modified example shown in FIG. 8, the gas supply holes 234a, 234b and 234c include a first group of holes that face the gas supply slits 235a, 235b and 235c and a second group of holes that do not face the gas supply slits 235a, 235b and 235c. Specifically, the holes of the first group facing the gas supply slits 235a, 235b and 235c are open toward the inner tube 12 and the holes of the second group not facing the gas supply slits 235a, 235b and 235c are open toward the connecting wall 18e. For example, the total opening area of the gas supply holes 234a (including the holes of the first group among the gas supply holes 234a and the holes of the second group among the gas supply holes 234a) may be set to be equal to the total opening area of the gas supply holes 234a according to the first modified example shown in FIG. 7. The same applies to the total opening area of the gas supply holes 234c according to the second modified example and the total opening area of the gas supply holes 234c according to the first modified example. Further, the total opening area of the gas supply holes 234b (including the holes of the first group among the gas supply holes 234b and the holes of the second group among the gas supply holes 234b) may be set to be equal to the total opening area of the gas supply holes 234b according to the first modified example shown in FIG. 7.

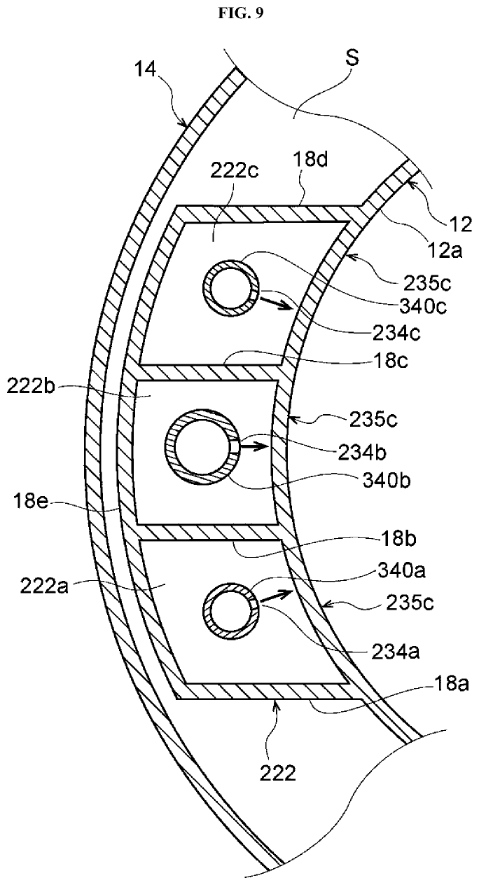

According to the third modified example shown in FIG. 9, some gas supply holes (also indicated by the reference numerals 234a, 234b and 234c in FIG. 9) are additionally provided at the gas supply nozzles 340a, 340b and 340c, respectively, below the wafer arrangement region. For example, the additional gas supply holes 234a, 234b and 234c are open toward the circumferential wall of the inner tube 12. FIG. 9 schematically illustrates a horizontal cross-section of the reaction tube 203 at a height corresponding to the boat support 218. The other holes of the gas supply holes 234a, 234b and 234c other than the additional gas supply holes may be arranged in the same manner as the present embodiments, the first modified example, the second modified example or the fourth modified example.

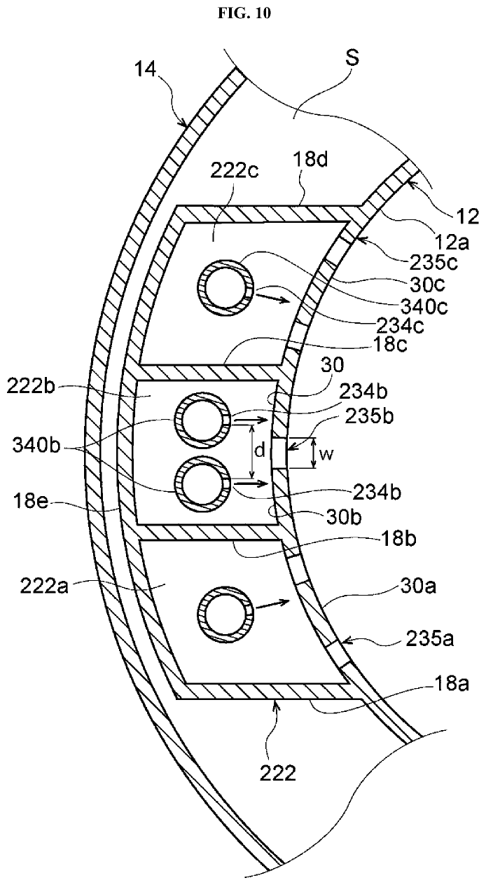

According to the fourth modified example shown in FIG. 10, the gas supply holes 234a, 234b and 234c are open toward a center of the reaction tube 203. According to the fourth modified example, an obstacle 30b such as a spoiler baffle plate is further arranged between the gas supply holes 234b and the gas supply slits 235b. Specifically, the circumferential wall of the inner tube 12 meets a straight line extending from each of the gas supply holes 234b along an ejection direction of the gas. According to the fourth modified example, the circumferential wall of the inner tube 12 constitutes the obstacle 30b. However, the configuration of the obstacle 30b is not limited to the illustrated configuration where the obstacle 30b is formed as an integrated body with the inner tube 12. For example, a configuration (such as an obstruction plate) capable of suppressing the process gas ejected through the gas supply holes 234b from directly passing through the gas supply slits 235b may also be used as the obstacle 30b.

For example, a width w of each of the gas supply slits 235b is narrower than a horizontal distance d between the gas supply holes 234b provided at the ascending pipe and the gas supply holes 234b provided at the descending pipe.

Further, obstacles 30a and 30c are arranged between the gas supply holes 234a and the gas supply slits 235a and between the gas supply holes 234c and the gas supply slits 235c, respectively. The obstacles 30a, 30b and 30c may be collectively referred to as obstacles 30. Each of the obstacles 30a through 30c is configured to form a wall substantially perpendicular to an ejection direction of the gas ejected from each of the gas supply holes 234a or 234c so as to meet a straight line extending from the gas supply holes 234a or 234c along the ejection direction. As a result, small openings may exist at two locations beside (left and right of) the obstacle 30a. The obstacles 30a through 30c may be of different shapes and arrangements depending on, for example, a type of each gas supply nozzle. Alternatively, only one of the obstacles 30a through 30c may be provided. When the return nozzle is provided in the nozzle arrangement chamber 222 (that is, the second chamber 222b) and the obstacle 30b alone is provided without the obstacles 30a and 30c being present, the inner tube 12 whose width is narrower than that of each of the gas supply slits 235a and that of each of the gas supply slits 235c may be used.

As described with reference to FIGS. 2 and 7 through 10, the process gas ejected from the gas supply holes 234 in each of the first chamber 222a, the second chamber 222b and the third chamber 222c may be deflected by hitting side surfaces of the nozzle arrangement chamber 222 (that is, the connecting wall 18e and the first partition 18a through the fourth partition 18d), the circumferential wall of the inner tube 12 or the obstacles 30. Thereby, the deviation in the flow velocity flowing from the gas supply slits 235 into the inner tube 12 may be decreased, and a pressure loss in the nozzle arrangement chamber 222 (that is, a difference between a pressure at the gas supply holes 234 and a pressure at the gas supply slits 235) may be increased. Therefore, it is possible to suppress the gas from being sucked into the nozzle arrangement chamber 222 through the nozzle insertion port 256. As a result, it is possible to suppress particles generated in a lower portion (furnace opening) of the reaction tube 203 from being transferred to the wafer arrangement region through the nozzle arrangement chamber 222, and it is also possible to suppress the used process gas floating in the lower portion from being mixed into the unused process gas ejected through the gas nozzles 340a, 340b and 340c. Further, it is possible to reduce a supply of a purge gas to the lower portion of the reaction tube 203 to prevent the above-described problems. It is also possible to uniformize a concentration distribution of the process gas concentration distribution in the wafer arrangement region.

The first gas exhaust port 236 is provided at the portion of the circumferential wall of the inner tube 12 facing a location where the nozzle arrangement chamber 222 is provided. The first gas exhaust port 236 is disposed such that the wafer arrangement region of the process chamber 201 in which the wafers 200 are accommodated is interposed between the first gas exhaust port 236 and the nozzle arrangement chamber 222. The first gas exhaust port 236 is provided from the lower end to the upper end of the wafer arrangement region of the process chamber 201 in which the wafers 200 are accommodated. The process chamber 201 and the gap S communicate with each other through the first gas exhaust port 236.

The second gas exhaust port 237 is provided at the circumferential wall of the inner tube 12 below the first gas exhaust port 236 of the inner tube 12. The second gas exhaust port 237 may be provided between a position higher than both an upper end of the exhaust port 230 and a lower end of the exhaust port 230. A plurality of second gas exhaust ports including the second gas exhaust port 237 (also simply referred to as “second gas exhaust ports 237”) may be provided, and one of the second gas exhaust ports 237 may be arranged so as to meet a straight line extending from the exhaust pipe 231 along an extending direction of the exhaust pipe 231. As described above, the first gas exhaust port 236 is provided so that the process chamber 201 and the gap S communicate with each other therethrough, and the second gas exhaust port 237 is provided so as to exhaust an atmosphere of a lower portion of the process chamber 201.

That is, the first gas exhaust port 236 serves as a gas exhaust port configured to exhaust the inner atmosphere of the process chamber 201 to the gap S. The gas exhausted through the first gas exhaust port 236 is exhausted to the outside of the reaction tube 203 through the exhaust port 230 and the exhaust pipe 231 via the gap S provided outside the inner tube 12. The gas exhausted through the second gas exhaust port 237 is exhausted to the outside of the reaction tube 203 through the exhaust port 230 and the exhaust pipe 231 via a lower portion of the gap S.

According to the configurations described above, after the gas passes through the wafers 200, the gas is exhausted by way of the outside of a cylinder of the inner tube 12. Thereby, it is possible to minimize a pressure loss by decreasing a pressure difference between a pressure of an exhauster such as the vacuum pump 246 and a pressure of the wafer arrangement region. In addition, by minimizing the pressure loss, it is possible to decrease the pressure of the wafer arrangement region and to mitigate the loading effect by increasing the flow velocity of the gas in the wafer arrangement.

As shown in FIG. 1, a main exhaust path 20 is formed to exhaust an inner atmosphere of the inner tube 12. The main exhaust path 20 is constituted by the first gas exhaust port 236 (which is an example of an outflow port provided at the circumferential wall of the inner tube 12 to face the gas supply slits 235a through 235c), the gap S and the exhaust port 230 provided at the outer tube 14.

As shown in FIG. 1, a subsidiary exhaust path 22 is also formed to exhaust the inner atmosphere of the inner tube 12. The subsidiary exhaust path 22 is constituted by the second gas exhaust port 237 (which is an example of an outflow port different from the outflow port provided at the circumferential wall of the inner tube 12 to face the gas supply slits 235a through 235c), the gap S and the exhaust port 230 provided at the outer tube 14.

FIG. 4 schematically illustrates a vertical cross-section of the reaction tube 203. In FIG. 4, the illustrations of components such as the boat 217 are omitted for simplification.

The gas supply slits 235a of a horizontally elongated slit shape and communicating with the first chamber 222a of the nozzle arrangement chamber 222 are provided on the circumferential wall of the inner tube 12 along the vertical direction. The gas supply slits 235b of a horizontally elongated slit shape and communicating with the second chamber 222b of the nozzle arrangement chamber 222 are provided on the circumferential wall of the inner tube 12 along the vertical direction on a side of the gas supply slits 235a. The gas supply slits 235c of a horizontally elongated slit shape and communicating with the third chamber 222c of the nozzle arrangement chamber 222 are provided on the circumferential wall of the inner tube 12 along the vertical direction on a side of the gas supply slits 235b.

Thereby, the gas supply slits 235a through 235c are arranged in a two-dimensional matrix including a plurality of columns and a plurality of rows arranged in the vertical and horizontal directions, respectively.

The circumferential lengths of the gas supply slits 235a through 235c along a circumferential direction of the inner tube 12 may be the same as the circumferential lengths of the chambers 222a, 222b and 222c in the nozzle arrangement chamber 222 along a circumferential direction of each chamber. Preferably, it is possible to improve a gas supply efficiency when the gas supply slits 235a through 235c are arranged in the two-dimensional matrix at locations other than a connection portion between the circumferential wall of the inner tube 12 and each of the partitions 18a through 18d.

Both ends of each of the gas supply slits 235a through 235c are formed as smooth curves corresponding to semicircles. Thereby, it is possible to suppress the stagnation of the gas around edges of the gas supply slits 235a through 235c, and it is also possible to suppress the formation of a film on the edges. It is also possible to prevent the film from being peeled off when the film is formed on the edges.

The nozzle insertion port 256 is provided at a region extending from a lower end of the inner tube 12 close to the nozzle arrangement chamber 222 to a lower end of the inner circumferential surface 12a. The nozzle insertion port 256 is used to install the gas nozzles 340a, 340b and 340c into the chambers 222a, 222b and 222c of the nozzle arrangement chamber 222.

Each of the nozzle supports 350a through 350c may be constituted by a metal elbow pipe. The nozzle supports 350a through 350c are capable of supporting the gas nozzles 340a, 340b and 340c inserted at the upper ends thereof, respectively. The nozzle supports 350a through 350c fluidically communicates with the gas supply pipes 310a, 310b and 310c on side surfaces thereof, respectively. Further, the nozzle supports 350a through 350c are detachably attached to the manifold 226. When installing the gas nozzles 340a, 340b and 340c, after inserting the gas nozzles 340a, 340b and 340c into the corresponding chambers 222a, 222b and 222c through the nozzle insertion port 256, the nozzle supports 350a through 350c are fixed with fasteners such as bolts (not shown) while internal flow paths of the nozzle supports 350a through 350c are being connected to the gas supply pipes 310a, 310b and 310c.

As a result, as shown in FIG. 2, the gas nozzles 340a, 340b and 340c are accommodated in their corresponding chambers 222a, 222b and 222c of the nozzle arrangement chamber 222. Further, the gases are supplied through the gas nozzles 340a, 340b and 340c into the inner tube 12 via the gas supply slits 235a through 235c (which are an example of inflow ports provided in the inner tube 12 constituting the front wall of each chamber 222a, 222b and 222c). When the gases are supplied, it is possible to suppress each gas from flowing along the outer circumferential surface 12c of the inner tube 12 by the partitions 18a through 18d.

The partitions 18a through 18d of the nozzle arrangement chamber 222 extend vertically from a ceiling of the nozzle arrangement chamber 222 to locations higher than the lower end of the reaction tube 203. Specifically, as shown in FIG. 4, lower ends of the partitions 18b and 18c extend to locations lower than an upper edge of the nozzle insertion port 256. The lower ends of the partitions 18b and 18c extend to the locations higher the lower end of the reaction tube 203 lower than upper ends of the nozzle supports 350a through 350c.

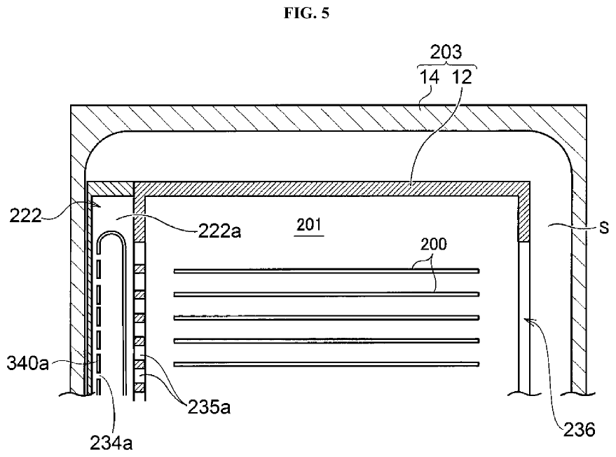

As shown in FIG. 5, the gas supply slits 235a through 235c are arranged in the vertical direction so as to face spaces between adjacent wafers among the wafers 200 supported in a multistage manner by the boat 217 accommodated in the process chamber 201. In FIG. 5, the illustration of the boat 217 is omitted for simplification.

It is preferable that the gas supply slits 235a through 235c are disposed at a region extending from a location facing a space between a lowermost wafer among the wafers 200 accommodated in the boat 217 and a bottom plate of the boat 217 to a location facing a space between an uppermost wafer among the wafers 200 and a top plate of the boat 217 in a manner that the gas supply slits 235a through 235c face the space between the lowermost wafer and the bottom plate, the space between the uppermost wafer and the top plate and spaces between the adjacent wafers among the wafers 200. With the above-described configurations of the gas supply slits 235a through 235c, it is possible to form a flow of the process gas on each of the wafers 200 in a direction parallel to each of the wafers 200. The flow parallel to each of the wafers 200 approximates to an ideal laminar flow when the flow velocity of the process gas is low, and tends to form a uniform flow from an upstream side to a downstream side thereof.

It is preferable that the gas supply holes 234a through 234c of the gas nozzles 340a through 340c are provided at locations corresponding to a center of the vertical width of each of the gas supply slits 235a through 235c in one-to-one correspondence with the gas supply slits 235 regardless of the ejection direction of each gas.

For example, in case the gas supply slits 235a are constituted by 25 gas supply slits arranged consecutively, it is preferable that the gas supply holes 234a are constituted by 25 gas supply holes arranged at the same intervals. The same applies to the gas supply slits 235b (the gas supply holes 234b) and the gas supply slits 235c (the gas supply holes 234c). The additional gas supply holes 234a through 234c shown in FIG. 9 are provided below the original gas supply holes 234a through 234c arranged corresponding to the gas supply slits 235a through 235c.

The first gas exhaust port 236 is not limited to one continuous opening provided commonly for the wafers 200. For example, similar to components such as the gas supply slits 235a, the first gas exhaust port 236 may be implemented by a plurality of openings provided respectively for the wafers 200. Further, components such as the gas supply holes 234a and the gas supply slits 235a are not limited to a plurality of openings provided respectively for the wafers 200. For example, similar to a component such as the first gas exhaust port 236, the components such as the gas supply holes 234a and the gas supply slits 235a may be implemented by one continuous opening commonly provided for the wafers 200 instead of the plurality of the openings. However, it is preferable that at least one among the gas supply holes 234, the gas supply slits 235 and the first gas exhaust port 236 are implemented by a plurality of openings provided respectively for the wafers 200.

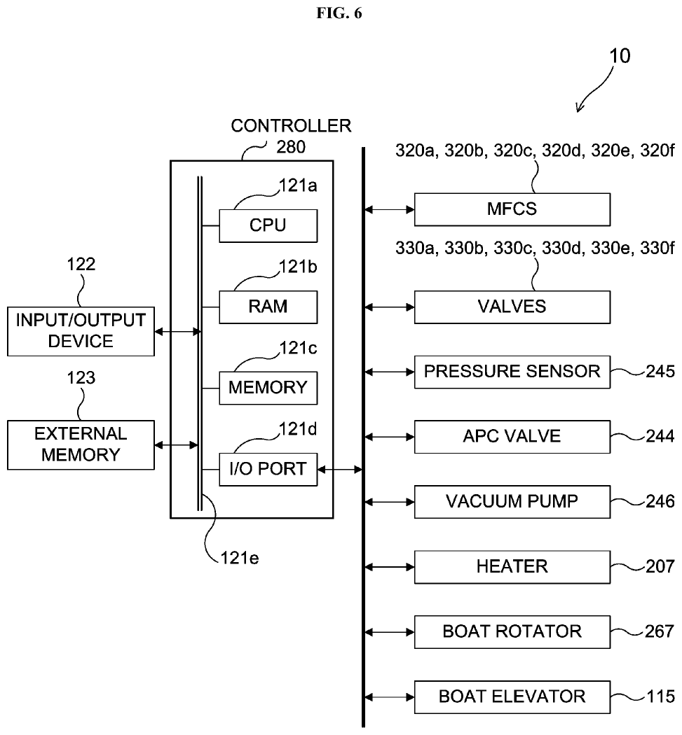

FIG. 6 is a block diagram schematically illustrating a configuration of a controller 280 of the substrate processing apparatus 10 and related components of the substrate processing apparatus 10. The controller 280 serving as a control device (control structure) is constituted by a computer including a CPU (Central Processing Unit) 121a, a RAM (Random Access Memory) 121b, a memory 121c and an I/O port 121d.

The RAM 121b, the memory 121c and the I/O port 121d may exchange data with the CPU 121a through an internal bus 121e. For example, an input/output device 122 such as a touch panel is connected to the controller 280.

For example, the memory 121c is configured by components such as a flash memory and HDD (Hard Disk Drive). A control program for controlling the operation of the substrate processing apparatus 10 or a process recipe containing information on the sequences and conditions of a substrate processing described later is readably stored in the memory 121c.

The process recipe is obtained by combining steps of the substrate processing described later such that the controller 280 can execute the steps to acquire a predetermine result, and functions as a program. Hereinafter, the process recipe and the control program are collectively or individually referred to as a “program”.

In the present specification, the term “program” may indicate the process recipe alone, may indicate the control program alone, or may indicate both of the process recipe and the control program. The RAM 121b functions as a memory area (work area) where a program or data read by the CPU 121a is temporarily stored.

The I/O port 121d is connected to the above-described components such as the MFCs 320a through 320f, the valves 330a through 330f, the pressure sensor 245, the APC valve 244, the vacuum pump 246, the heater 207, the temperature sensor (not shown), the boat rotator 267 and the boat elevator 115.

The CPU 121a is configured to read the control program from the memory 121c and execute the control program. In addition, the CPU 121a is configured to read the process recipe from the memory 121c according to an instruction such as an operation command inputted from the input/output device 122.

According to the contents of the process recipe read from the memory 121c, the CPU 121a may be configured to control various operations such as flow rate adjusting operations for various gases by the MFCs 320a through 320f, opening/closing operations of the valves 330a through 330f, an opening/closing operation of the APC valve 244. The CPU 121a may be further configured to control various operations such as a pressure adjusting operation by the APC valve 244 based on the pressure sensor 245, a start and stop of the vacuum pump 246, a temperature adjusting operation of the heater 207 based on the temperature sensor (not shown). The CPU 121a may be further configured to control various operations such as an operation of adjusting rotation and rotation speed of the boat 217 by the boat rotator 267 and an elevating and lowering operation of the boat 217 by the boat elevator 115.

The controller 280 is not limited to a dedicated computer. The controller 280 may be embodied by a general-purpose computer. For example, the controller 280 according to the present embodiments may be embodied by preparing an external memory 123 and installing the program onto the general-purpose computer using the external memory 123. For example, the external memory 123 may include a magnetic disk such as a hard disk drive (HDD), an optical disk such as a CD, a magneto-optical disk such as an MO, a semiconductor memory such as a USB memory.

The method of providing the program to the computer is not limited to the external memory 123. For example, the program may be directly provided to the computer by a communication means such as the Internet and a dedicated line instead of the external memory 123. The memory 121c and the external memory 123 may be embodied by a non-transitory computer-readable recording medium. Hereinafter, the memory 121c and the external memory 123 may be collectively or individually referred to as a recording medium. In the present specification, the term “recording medium” may refer to the memory 121c alone, may refer to the external memory 123 alone, or may refer to both of the memory 121c and the external memory 123.

<Operation>

Hereinafter, the operation of the substrate processing apparatus 10 according to the present embodiments will be described according to a control procedure performed by the controller 280.

A method of manufacturing a semiconductor device according to the present embodiments includes: (a) loading the wafers 200 into the reaction tube 203 of the substrate processing apparatus 10 including: the reaction tube 203 (that is, the process vessel) capable of accommodating the wafers 200 vertically arranged along the vertical direction (arrangement direction) wherein the wafers 200 are processed in the reaction tube; the gas nozzles 340a, 340b, 340c (also collectively referred to as a nozzle) provided in the reaction tube 203, provided with the gas supply holes 234 serving as the first openings arranged along the vertical direction and configured to distribute and supply the gas to the wafers 200; and the nozzle arrangement chamber 222 serving as the supply buffer provided in the reaction tube 203, capable of accommodating the gas nozzles 340a, 340b, 340c, and provided with the gas supply slits 235 serving as the second openings arranged along the vertical direction and open toward the wafer arrangement region of the reaction tube 203 to restrict fluid communication therearound, wherein at least one among the gas supply holes 234 is arranged to be prevented from directly facing the gas supply slits 235 serving as the second openings; and (b) processing the wafers 200 in the reaction tube 203 by supplying the gas into the reaction tube 203 through the gas nozzles 340a, 340b and 340c.

The boat 217 on which a predetermined number of the wafers 200 are placed is inserted into the reaction tube 203 in advance, and the reaction tube 203 is airtightly closed by the seal cap 219.

When a control operation by the controller 280 is started, the controller 280 operates the vacuum pump 246 and the APC valve 244 to exhaust an inner atmosphere of the reaction tube 203 through the exhaust port 230 (an exhaust procedure).

For example, after the exhaust procedure is completed (after a predetermined time has elapsed), the controller 280 opens the valves 330b and 330f to supply the silicon (Si) source gas serving as the second source gas together with the nitrogen gas serving as a carrier gas through the gas nozzle 340b. In parallel with supplying the silicon source gas, the controller 280 closes the valve 330a and opens the valves 330c through 330f to supply the nitrogen (N₂) gas serving as the inert gas through the gas nozzles 340a and 340c through 340f to process the wafers 200. Thereby, a layer is formed on the wafers 200 (a first processing procedure).

In the first processing procedure, the controller 280 operates the vacuum pump 246 and the APC valve 244 to discharge the inner atmosphere of the reaction tube 203 through the exhaust port 230 to apply a negative pressure in the reaction tube 203 such that the pressure value obtained from the pressure sensor 245 becomes constant.

As a result, the second source gas flows in parallel on the wafers 200, then flows from an upper portion to a lower portion of the gap S through the first gas exhaust port 236 and the second gas exhaust port 237, and is exhausted through the exhaust port 230 and the exhaust pipe 231.

In the first processing procedure, the inert gas is supplied toward the centers of the wafers 200 through the gas nozzles 340a and 340c through 340e. When supplying the inert gas, by controlling the supply amount of the inert gas through the gas nozzles 340a and 340c through 340e by the controller 280, a concentration of the inert gas in central portions of the wafers 200 is lower than a concentration of the inert gas in outer peripheral portions of the wafers 200. Thereby, it is possible to control an amount of the second source gas (or active species) supplied to surfaces of the wafers 200. As a result, it is possible to adjust a thickness distribution of the film formed on the surface of the wafer 200 from a central concave distribution to a substantially flat distribution or a substantially central convex distribution.

For example, after the first processing procedure is completed (after a predetermined time has elapsed), the controller 280 closes the valve 330b to stop the supply of the second source gas through the gas nozzle 340b, and opens the valve 330f to supply the inert gas through the gas nozzle 340b. Further, the controller 280 exhausts the inner atmosphere of the reaction tube 203 through the exhaust port 230 by setting a low target pressure by the APC valve 244. In parallel with exhausting the inner atmosphere of the reaction tube 203, the controller 280 opens the valves 330a and 330c to supply the inert gas through the gas nozzles 340a and 340c such that the gas staying in the reaction tube 203 is purged out through the exhaust port 230 (a first purge out procedure).

Subsequently, after the first purge out procedure is completed (after a predetermined time has elapsed), the controller 280 opens the valves 330a and 330e to supply the ammonia (NH₃) gas serving as the first source gas together with the nitrogen (N₂) gas serving as the carrier gas through the gas nozzle 340a. In parallel with supplying the ammonia gas, the controller 280 closes the valve 330b and opens the valves 330c, 330d and 330f to eject a small amount of the nitrogen (N₂) gas through the gas nozzles 340a, 340c, 340d and 340f to process the wafers 200 (a second processing procedure).

In the second processing procedure, the controller 280 operates the vacuum pump 246 and the APC valve 244 to discharge the inner atmosphere of the reaction tube 203 through the exhaust port 230 to apply the negative pressure in the reaction tube 203 such that the pressure value obtained from the pressure sensor 245 becomes constant.

As a result, the first source gas flows in parallel on the wafers 200, then flows from the upper portion to the lower portion of the gap S through the first gas exhaust port 236 and the second gas exhaust port 237, and is exhausted through the exhaust port 230 and the exhaust pipe 231.

For example, after the second processing procedure is completed (after a predetermined time has elapsed), the controller 280 closes the valve 330a to stop the supply of the first source gas through the gas nozzle 340a. Further, the controller 280 exhausts the inner atmosphere of the reaction tube 203 through the exhaust port 230 by controlling the vacuum pump 246 and the APC valve 244 to increase the negative pressure applied into the reaction tube 203. In parallel with exhausting the inner atmosphere of the reaction tube 203, the controller 280 opens the valves 330a and 330c to supply the inert gas through the gas nozzles 340a and 340c such that the gas staying in the gap S provided between the inner tube 12 and the outer tube 14 is purged out through the exhaust port 230 (a second purge out procedure). In the second purge out procedure, the controller 280 opens the valve 330b to supply the inert gas through the gas nozzle 340b.

When the substrate processing of the wafer 200 is completed by repeatedly performing a cycle including the first processing procedure, the first purge out procedure, the second processing procedure and the second purge out procedure a predetermined number of times, the boat 217 is transferred (unloaded) out of the reaction tube 203 in the order reverse to that of the loading of the boat 217 described above. In addition, the wafers 200 are transferred from the boat 217 to a pod of a transfer shelf (not shown) by a wafer transfer device (not shown), and the pod is transferred from the transfer shelf to a pod stage by a pod transfer device (not shown). Then, the pod is transferred to the outside of a housing of the substrate processing apparatus 10 by an external transfer device (not shown).

According to the embodiments and the modified examples described above, it is possible to provide one or more of the following effects.

(a) When the process gas is ejected through the gas nozzles 340a through 340c accommodated in the first chamber 222a, the second chamber 222b and the third chamber 222c (that is, the supply buffer), respectively, the gas around the first chamber 222a, the second chamber 222b and the third chamber 222c is suppressed from being sucked thereinto, thereby efficiently supplying the process to the wafers 200, and keeping an inner atmosphere of the nozzle arrangement chamber 222 clean.

(b) It is possible to maintain inner pressures of the first chamber 222a, the second chamber 222b and the third chamber 222c higher than the inner pressures of the inner tube 12, and it is also possible to prevent the gas containing the particles from being sucked through the lower ends of the first chamber 222a, the second chamber 222b and the third chamber 222c. Thereby, it is possible to prevent the particles from being scattered on the wafers 200.

(c) It is possible to reduce an amount of the purge gas supplied to the lower portion of the reaction tube 203 in order to suppress the adhesion of by-products and the generation of the particles. It is also possible to improve the uniformity between wafers 200.

(d) A plurality of methods may be used to appropriately increase the inner pressure of the nozzle arrangement chamber 222 according to various types of the gas nozzles in use. Many of these methods may be implemented by minor hardware changes in the spatial orientation of the gas supply holes 234a through 234c of the gas nozzles 340a through 340c.

### EXAMPLES

According to the present embodiments, at least one among the gas supply holes 234 may be arranged to be prevented from directly facing the gas supply slits 235. Differences in the flow velocity and a partial pressure of the gas on the wafer 200 made by the change in the spatial orientation of the gas supply holes 234 as described above are analyzed by the simulation.

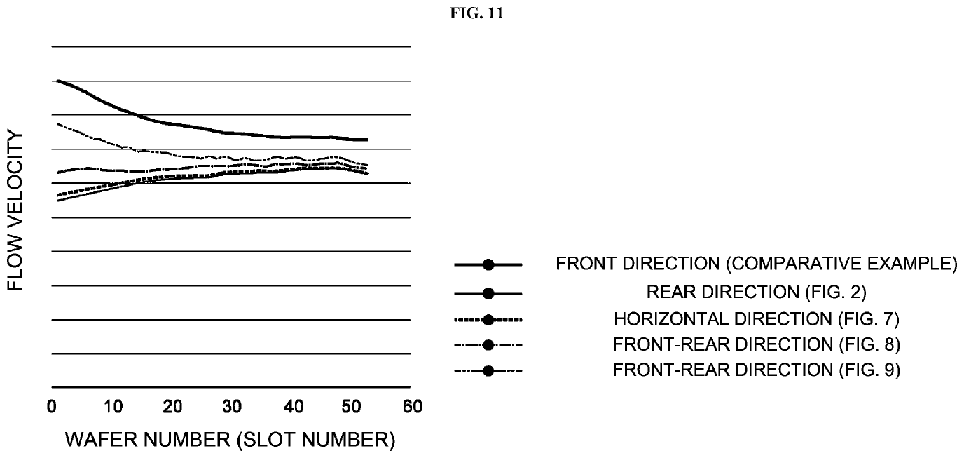

FIG. 11 is a line graph schematically illustrating the flow velocity of the gas on the center of each of the wafers 200. A horizontal axis shown in FIG. 11 represents a wafer number counted from the bottom of the boat 217, and a vertical axis FIG. 11 represents the flow velocity at the center of each of the wafers 200. A comparative example is a configuration in which the gas supply holes 234 are arranged so as to face the gas supply slits 235. The other configurations of the comparative example are the same as those of the present embodiments shown in FIGS. 2 and 7 through 9. From FIG. 11, it is confirmed that the flow velocity of the gas on the center of each of the wafers 200 is reduced by about 10% by changing the spatial orientation of the gas supply holes 234. In order to approximate the flow velocity to that of the comparative example, it is possible to adjust the flow velocity by. for example, increasing an introduction flow rate of the process gas or lowering the pressure.

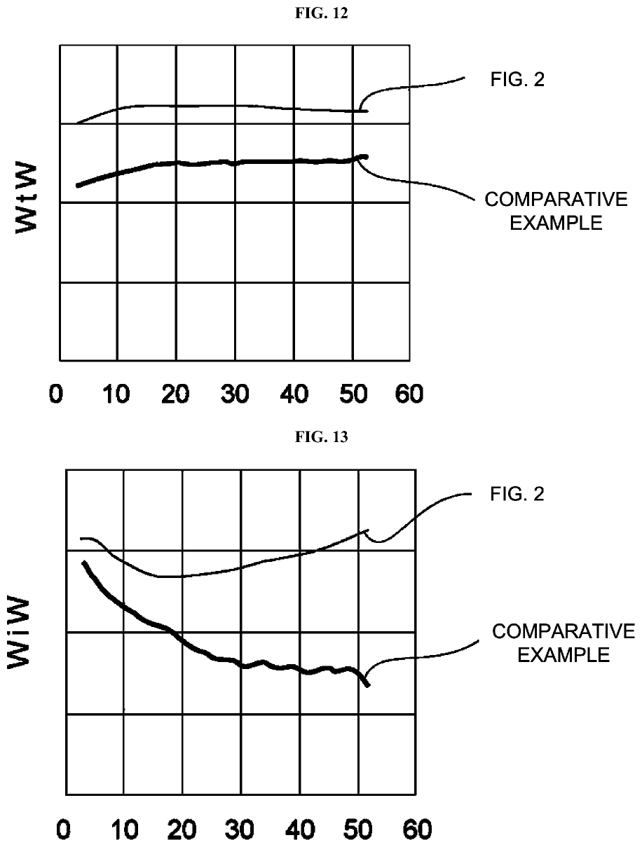

FIGS. 12 and 13 are line graphs schematically illustrating the partial pressure of the active species generated by the decomposition of the source gas. In FIGS. 12 and 13, thick lines indicate a comparative example in which the gas supply holes 234 are arranged so as to face the gas supply slits 235. A vertical axis shown in FIG. 12 represents an average value of the partial pressure of the active species on each wafer (which is wafer-to-wafer (WtW) characteristics of each wafer). From FIG. 11, it is confirmed that it is possible to obtain an equivalent or improved uniformity in comparison with the comparative example. FIG. 13 schematically illustrates the non-uniformity of the partial pressure of the active species on each wafer (which is within-wafer (WiW) characteristics of each wafer). In the present specification, the non-uniformity of the partial pressure refers to a value obtained by dividing the difference between the partial pressure on the outer periphery of the wafer and the partial pressure on the center of the wafer by the average value of the partial pressure. It is confirmed that, in the configuration of the present embodiments, the change in the non-uniformity of the partial pressure is smaller than that of the partial pressure in the comparative example. Since the non-uniformity is related to the convexity and can be controlled by the flow rate of the inert gas supplied through the gas nozzles 340a, 340c through 340e, the non-uniformity remaining constant between the wafers 200 is more important than the magnitude of the non-uniformity.

In FIGS. 12 and 13, the configurations of the comparative example and the present embodiments are compared under the same conditions except for the spatial orientation of the gas supply holes. Therefore, the flow rate of the gas may not be sufficiently optimized for the configuration of the present embodiments. In particular, the purge gas (N₂ gas) additionally supplied to the bottom of the reaction tube 203 in order to prevent the generation of the particles can be reduced in the present embodiments. Therefore, there is room for improvement in the within-wafer (WiW) characteristics.

### OTHER EMBODIMENTS

While the technique is described in detail by way of the embodiments and the modified examples, the above-described technique is not limited thereto. The above-described technique may be modified in various ways without departing from the scope thereof. Therefore, the scope of the technique described herein should be construed as defined in the following claims.

As described above, according to some embodiments in the present disclosure, it is possible to prevent the particles from being scattered on the substrates.

What is claimed is:

1. A substrate processing apparatus comprising:
a process vessel accommodating a plurality of substrates comprising a substrate and vertically arranged along an arrangement direction wherein the plurality of the substrates are processed in the process vessel;
a nozzle provided in the process vessel, provided with a plurality of first openings arranged along the arrangement direction and configured to distribute and supply a gas to the plurality of the substrates; and
a supply buffer provided in the process vessel, accommodating the nozzle, and provided with a plurality of second openings arranged along the arrangement direction and open toward a substrate arrangement region in the process vessel where the plurality of the substrates are arranged,
wherein at least one among the first openings is arranged to be prevented from directly facing the plurality of the second openings.

2. The substrate processing apparatus of claim 1, wherein the plurality of the second openings are provided at locations corresponding to positions of the plurality of the substrates accommodated in the process vessel.

3. The substrate processing apparatus of claim 2, wherein the supply buffer is provided with a nozzle insertion port disposed lower than the plurality of the first openings, and the supply buffer communicates fluidically with the substrate arrangement region through the nozzle insertion port when the plurality of the substrates are processed.

4. The substrate processing apparatus of claim 2, wherein the at least one among the first openings is open toward a radial direction of the process vessel, and the nozzle is configured such that the gas ejected through the at least one among the first openings hits a wall of the supply buffer provided opposite to a side surface of the supply buffer on which the plurality of the second openings are provided.

5. The substrate processing apparatus of claim 2, wherein the at least one among the first openings is open toward a circumferential direction of the process vessel, and the nozzle is configured such that the gas ejected through the at least one among the first openings hits a wall of the supply buffer on which none of the second openings are provided.

6. The substrate processing apparatus of claim 2, wherein at least one among the first openings is open toward a radial direction of the process vessel whereas at least one among the first openings is open toward a center of the process vessel, and the nozzle is configured such that the gas ejected through the at least one among the first openings open toward the radial direction of the process vessel hits a wall of the supply buffer provided opposite to a side surface of the supply buffer on which the plurality of the second openings are provided.

7. The substrate processing apparatus of claim 2, wherein the at least one among the first openings is open at locations at which none of the second openings are located along the arrangement direction, and the nozzle is configured such that the gas ejected through the at least one among the first openings hits a wall of the supply buffer or a wall of the process vessel on which none of the second openings are provided.

8. The substrate processing apparatus of claim 2, wherein the process vessel comprises an inner tube in which the plurality of the substrates are arranged and an outer tube provided outside the inner tube, and the nozzle is provided between the inner tube and the outer tube.

9. The substrate processing apparatus of claim 1, wherein consecutive openings among the first openings are arranged at a same interval along the arrangement direction or are formed with a same opening area.

10. The substrate processing apparatus of claim 1, further comprising
an obstacle disposed at a location on a straight line extending from each of the first openings along an ejection direction of the gas.

11. The substrate processing apparatus of claim 1, wherein the nozzle comprises a nozzle array constituted by a first pipe and a second pipe extending in the arrangement direction and communicating with each other so as to make it possible to eject a same gas through the first pipe and the second pipe,
the plurality of the first openings are provided at both the first pipe and the second pipe at locations corresponding to positions of the plurality of the substrates, and
a width of each of the second openings is narrower than a horizontal distance between each first opening provided at the first pipe and each first opening provided at the second pipe.

12. The substrate processing apparatus of claim 1, wherein the process vessel is provided with one or more gas exhaust ports provided over the substrate arrangement region.

13. The substrate processing apparatus of claim 1, wherein the supply buffer comprises a plurality of nozzle arrangement chambers arranged side by side in a circumferential direction, and
the plurality of the second openings are provided in the plurality of the nozzle arrangement chambers in a manner that widths of the second openings are different between the nozzle arrangement chambers.

14. The substrate processing apparatus of claim 1, wherein the supply buffer comprises three nozzle arrangement chambers, and
a width of each second opening provided at a nozzle arrangement chamber among the three nozzle arrangement chambers interposed between the other two nozzle arrangement chambers is smaller than a width of each second opening provided at the other two nozzle arrangement chambers.

15. The substrate processing apparatus of claim 12, wherein the supply buffer comprises a plurality of nozzle arrangement chambers arranged side by side in a circumferential direction, and
a width of each second opening provided at a nozzle arrangement chamber among the nozzle arrangement chambers located so as to face a gas exhaust port via a center of each of the substrates is smaller than a width of each second opening provided at the other nozzle arrangement chambers.
